(19) United States
(12) Patent Application Publication
(10) Pub. No.: US 2014/0262467 A1
(43) Pub. Date: Sep. 18, 2014

(54) CONTACT SURFACE FOR A PIN HOLE

(71) Applicant: Shan-Jui Lu, Xizhi City (TW)

(72) Inventor: Shan-Jui Lu, Xizhi City (TW)

(73) Assignee: Lantek Electronics Inc., Xizhi City (TW)

(21) Appl. No.: 14/215,651

(22) Filed: Mar. 17, 2014

Related U.S. Application Data
(60) Provisional application No. 61/789,087, filed on Mar. 15, 2013.

(51) Int. Cl. H05K 1/11

(52) U.S. Cl. CPC H05K 1/111
USPC 174/261

(57) ABSTRACT

The present invention relates to an improved contact surface of pin hole (e.g, a ground pin hole, screw fastening hole, or the like), which is adopted on a substrate, the substrate is formed with at least a pin hole (e.g, a ground pin hole, screw fastening hole, or the like) hole and characterized in that: the periphery of the pin hole (e.g, a ground pin hole, screw fastening hole, or the like) is formed with plural soldering joints and plural penetrated holes, thereby allowing a pin (e.g., pin, ground pin, screw, or the like) and the substrate to be formed with an excellent contact surface for achieving a grounding effect.

### CROSS-REFERENCE TO RELATED APPLICATIONS

This application claims benefit under 35 U.S.C. §119(e) of U.S. Provisional Application Ser. No. 61/789,087, entitled “IMPROVED CONTACT SURFACE FOR A PIN HOLE,” filed Mar. 15, 2013, naming Shan-Jui Lu as the inventor, the complete disclosure being incorporated herein by reference.

### BACKGROUND OF THE INVENTION

1. Field of the Invention

The present invention relates to an improved contact surface arrangement for a substrate (e.g., a printed circuit board), and specifically to an improved contact surface which is situated about the periphery of a pin hole (e.g, a ground pin hole, screw fastening hole, or the like) formed in a substrate and in which the improved contact surface is formed with a plurality of soldering joints and a plurality of penetrated holes thereby allowing a pin, ground pin, screw or the like and the substrate to be formed with an excellent contact surface for, among other things, achieving a grounding effect.

2. Description of Related Art

Referring to FIG. 1(a) and FIG. 1(b), wherein FIG. 1(a) is a schematic view illustrating a contact surface of a conventional screw fastening hole; and FIG. 1(b) is a schematic view illustrating the contact surface of conventional screw fastening hole after passing through a tin soldering furnace. As shown in FIGS. 1(a) and 1(b), a conventional substrate 100 is often formed with a plurality of screw fastening holes 110. The periphery of each of the screw fastening holes 110 is formed with a plurality of penetrated holes 120, and the periphery of each of the penetrated holes 120 is formed with a soldering surface 130. As such, after passing a tin furnace, tin is provided in the penetrated hole 120 and soldered on the soldering surface 130. However, the soldering surface 130 provided with tin is not flat nor smooth, and the screw fastening hole 110 may even be plugged, thus a manual operation of trimming and cleaning has to be performed, thereby increasing the production cost.

The present invention provides an improved contact surface of a pin hole (e.g, a ground pin hole, screw fastening hole, or the like) for improving the mentioned shortages of the conventional contact surface of the pin hole.

### SUMMARY OF THE INVENTION

One primary objective of the present invention is to provide an improved contact surface of a pin hole (e.g, a ground pin hole, screw fastening hole, or the like) in which the periphery of a pin hole is formed with a plurality of soldering joints and a plurality of penetrated holes, thereby allowing a pin, screw or the like and a substrate to be formed with an excellent contact surface for achieving a grounding effect.

Another objective of the present invention is to provide an improved contact surface of a pin hole in which each soldering joint is formed with a plurality of small soldering points arranged in a triangular arrangement.

Another objective of the present invention is to provide an improved contact surface of a pin hole in which a small surface mount device (SMD) is protected from being broken and surface lifting is prevented when a substrate is assembled.

Still another objective of the present invention is to provide an improved contact surface of a pin hole in which the pin hole is prevented from being plugged while a substrate passes through a soldering furnace (e.g., a tin soldering furnace), thereby avoiding trimming and cleaning operations.

For achieving the above-mentioned objectives, the present invention provides an improved contact surface arrangement situated in relation to a pin hole (e.g, a ground pin hole, screw fastening hole, or the like), which is adopted on a substrate, the substrate is formed with at least a pin hole and characterized in that: the periphery of the pin hole is formed with plural soldering joints and plural penetrated holes.

### BRIEF DESCRIPTION OF THE DRAWINGS

The present invention will be apparent to those skilled in the art by reading the following detailed description of a preferred embodiment thereof, with reference to the attached drawings, in which:

FIG. 1(a) is a schematic view illustrating a contact surface for a conventional screw fastening hole;

FIG. 1(b) is a schematic view illustrating the contact surface of conventional screw fastening hole of FIG. 1(a) after passing through a tin soldering furnace;

FIG. 2 is a schematic view illustrating the improved contact surface for a pin hole formed in a substrate, according to a preferred embodiment of the present invention; and

FIG. 3 is a schematic view illustrating the improved contact surface of a pin hole of FIG. 2 after passing through a soldering furnace, according to a preferred embodiment of the present invention.

### DETAILED DESCRIPTION OF THE PREFERRED EMBODIMENT

Referring to FIG. 2 and FIG. 3, wherein FIG. 2 is a schematic view illustrating the improved contact surface arrangement for a pin hole (e.g, a ground pin hole, screw fastening hole, or the like) formed in a substrate, according to a preferred embodiment of the present invention; and FIG. 3 is a schematic view illustrating the improved contact surface of FIG. 2 after passing through a soldering furnace (e.g., a tin soldering furnace) for being provided with solder (e.g., tin), according to a preferred embodiment of the present invention.

As shown in FIGS. 2 and 3, the improved contact surface for a pin hole (e.g, a ground pin hole, screw fastening hole, or the like) formed in a substrate provided by the present invention is adopted on a substrate 10. The substrate 10 is formed with at least a pin hole 20 (e.g, a ground pin hole, screw fastening hole, or the like), and the improved contact surface is characterized in that: the periphery of the pin hole 20 is formed with plural soldering joints 30 and plural penetrated holes 40.

The substrate 10 (e.g., a printed circuit board) includes at least one pin hole 20 formed thereon or therethrough. According to this embodiment, two pin holes are shown for illustration and shall not be seen as a limitation to the scope of the present invention.

The pin hole 20 may be in the form of a ground pin hole, which allows a ground pin to pass therethrough or be disposed therein. Alternatively, the pin hole 20 may be in the form of a screw fastening hole, which allows a screw (not shown in the figures) to pass therethough or be disposed therein, thereby enabling the screw to be fastened and locked on a casing (not shown in figures). The casing may be in the form of a metal casing or a plastic casing. According to this embodiment, a ground pin hole, a screw fastening hole, ground pin, screw and metal casing are adopted for illustration and shall not be seen as a limitation to the scope of the present invention.

The plural soldering joints 30 are arranged at the periphery of the pin hole 20, thereby allowing the substrate 10 to be provided with solder (e.g., tin) while passing through a soldering furnace (not shown in figures) for increasing the grounding area. In addition, the plural soldering joints 30 are arranged on a grounding surface (not shown in figures) of the substrate 10.

Moreover, the plural soldering joints 30 and the plural penetrated holes 40 are adjacently arranged or staggeringly arranged. The plural soldering joints 30 and the plural penetrated holes 40 may be formed separate and apart from each other. As shown in FIG. 2, the plural penetrated holes 40 are arranged with a means of two penetrated holes 40 being adjacently disposed and then a soldering joint 30 being provided. The aforesaid arrangement is served as an example for illustration and shall not be seen as a limitation to the scope of the present invention. The arrangement may also include a penetrated hole 40 and a soldering joint 30 being staggeringly disposed (not shown in figures).

Furthermore, each of the soldering joints 30 is further formed with plural small soldering points 31. In one embodiment, as shown, the quantity of the small soldering points is three, and the small soldering points 31 are arranged in a triangular arrangement.

The plural penetrated holes 40 are respectively provided with copper (not shown in figures). Solder (e.g., tin) is provided to the other surface of the substrate 10 through the penetrated holes 40 while passing through a soldering furnace, such that after being cooled, solder (e.g., tin) is filled in the penetrated holes 40.

As shown in FIG. 3, after the substrate 10 of the present invention passes through the soldering furnace, solder (e.g., tin) fills the other surface of the substrate 10 through the penetrated holes 40. Solder (e.g., tin) is also formed on the surface of the small soldering point 31. As such, the contact surface for the pin hole 20 is uniformly provided with tin, thereby forming a flat and smooth soldered (e.g., tin) surface. When the substrate 10 is assembled, a situation of surface lifting is prevented, such that a small surface mount device (SMD) is protected from being broken. Also, trimming and cleaning operations due to the pin hole 20 being plugged while the substrate 10 passing the soldering furnace are avoided. Moreover, a smooth contact surface is formed between the pin (e.g., screw or ground pin), the substrate 10, the penetrated holes 40, and the soldering joints 30 (via the small soldering points 31). If the plural soldering joints 30 are arranged on a grounding surface of the substrate, the contact surface formed between the pin (e.g., screw or ground pin), the substrate 10, the penetrated holes 40 and the soldering joints 30 achieve an excellent grounding effect.

As what has been disclosed above, the improved contact surface of a pin hole (e.g, a ground pin hole, screw fastening hole, or the like) provided by the present invention has following advantages: the contact surface of pin hole is uniformly provided with solder (e.g, tin), thereby forming a flat and smooth soldered (e.g., tin) surface. When the substrate 10 is assembled, a situation of surface lifting is prevented, so a small surface mount device (SMD) is protected from being broken. Also, trimming and cleaning operations due to the pin hole 20 being plugged while the substrate 10 passing the soldering furnace may be avoided. Moreover, a smooth contact surface is formed between the pin (e.g., screw or ground pin), the substrate 10 and the improved contact surface arrangement, thereby achieving an excellent grounding effect if the soldering joints 30 are arranged in relation to a grounding surface of the substrate. As such, the improved contact surface arrangement for a pin hole provided by the present invention is novel comparing to the conventional art.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific examples of the embodiments disclosed and that modifications and other embodiments are intended to be included within the scope of the appended claims. Although specific terms are employed herein, they are used in a generic and descriptive sense only and not for purposes of limitation.

What is claimed is:

1. An improved contact surface of screw fastening hole, being adopted on a substrate, said substrate being formed with at least a screw fastening hole and characterized in that: the periphery of said screw fastening hole being formed with plural soldering joints and plural penetrated holes.

2. The improved contact surface of screw fastening hole as claimed in claim 1, wherein said substrate is a printed circuit board.

3. The improved contact surface of screw fastening hole as claimed in claim 1, wherein said plural soldering joints and said plural penetrated holes are adjacently arranged or staggeringly arranged.

4. The improved contact surface of screw fastening hole as claimed in claim 1, wherein each of said soldering joints is further formed with plural small soldering points.

5. The improved contact surface of screw fastening hole as claimed in claim 4, wherein said small soldering point is a round soldering point.

6. The improved contact surface of screw fastening hole as claimed in claim 4, wherein the quantity of said small soldering point is three.

7. The improved contact surface of screw fastening hole as claimed in claim 6, wherein said plural small soldering points are arranged in a triangular arrangement.

8. The improved contact surface of screw fastening hole as claimed in claim 1, wherein said plural soldering joints are arranged on a grounding surface of said substrate.

9. An improved contact surface arrangement, comprising:
a substrate having a surface and defining a periphery for a pin hole formed in the substrate, said substrate further defining a plurality of penetrated holes, and
a plurality of soldering joints formed on the surface of the substrate, said soldering joints being situated in relation to the penetrated holes,
wherein the plurality of penetrated holes and soldering joints are situated about the periphery of the pin hole and are formed separate and apart from each other, such that when the substrate passes through a soldering furnace, solder is formed on the surface of the substrate through each of the penetrated holes and on the surface of the soldering joints.

10. The improved contact surface arrangement of claim 9, wherein said substrate is a printed circuit board.

11. The improved contact surface arrangement of claim 9, wherein said soldering joints and said penetrated holes are arranged adjacent to one another.

12. The improved contact surface arrangement of claim 9, wherein said soldering joints and said penetrated holes are arranged staggered from one another.

13. The improved contact surface arrangement of claim 9, wherein each of said soldering joints comprises a plurality of soldering points.

14. The improved contact surface arrangement of claim 13, wherein at least one of the soldering points is a round soldering point.

15. The improved contact surface arrangement of claim 13, wherein at least one of the soldering joints comprises at least three soldering points.

16. The improved contact surface arrangement of 15, wherein the soldering points are arranged in a triangular arrangement.

17. The improved contact surface arrangement of claim 9, wherein said soldering joints are arranged in relation to a grounding surface of said substrate.

18. The improved contact surface arrangement of claim 9, wherein the pin hole formed in the substrate is a screw fastening hole.

19. An improved contact surface arrangement, comprising:
a substrate having a grounding surface and defining a periphery of a pin hole formed in the substrate, said substrate further defining a plurality of penetrated holes, and
a plurality of soldering joints formed on the grounding surface of the substrate, said soldering joints being situated in relation to the penetrated holes,
wherein the plurality of penetrated holes and soldering joints are situated about the periphery of the pin hole and are formed separate and apart from each other, such that when the substrate passes through a soldering furnace, solder is formed on the grounding surface of the substrate, in each of the penetrated holes and on the surface of the soldering joints thereby forming a grounded contact surface between a pin disposed in the pin hole, the substrate, the penetrated holes and the soldering joints.

20. The improved contact surface arrangement of claim 10, wherein the pin hole formed in the substrate is a screw fastening hole, and wherein solder is formed on the grounding surface of the substrate, in each of the penetrated holes and on the surface of the soldering joints thereby forming a grounded contact surface between a screw disposed in the screw fastening hole, the substrate, the penetrated holes and the soldering joints.
